(19) United States
(12) Patent Application Publication
(10) Pub. No.: US 2026/0240041 A1
(43) Pub. Date: Aug. 13, 2026

(54) SEMICONDUCTOR DEVICE AND METHOD OF MAKING THE SAME

(71) Applicant: Taiwan Semiconductor Manufacturing Co., Ltd., Hsinchu (TW)

(72) Inventors: Po-Yuan Teng, Hsinchu (TW); Kuo-Lung Pan, Hsinchu (TW); Chih Wang, Hsinchu (TW); Wei-Yu Tsai, Miaoli County (TW); Hao-Yi Tsai, Hsinchu (TW); An-Jhih Su, Taoyuan (TW); Yen-Liang Lin, Taichung (TW)

(21) Appl. No.: 19/053,155

(22) Filed: Feb. 13, 2025

(51) Int. Cl. H01L 23/00; H01L 23/40; H01L 25/18

(52) U.S. Cl. CPC H10W 90/00; H10W 40/613; H10W 42/121; H10W 40/60; H10W 70/09; H10W 70/60; H10W 70/6528; H10W 90/22

(57) ABSTRACT

In some embodiments, a method is described that includes forming a first electrically conductive material in first opening of a first masking structure to provide a first conductive line, and forming a second electrically conductive material in second opening of a second masking structure to provide a conductive via. The second masking structure may be removed, and a dielectric layer is formed covering the first conductive line and the conductive via. The method may further include planarizing the dielectric layer to expose an upper surface of the conductive via, and forming an under-bump metallurgy on the planarized surface of the conductive via. The under-bump metallurgy may include an seed layer that covers an interface between the under-bump metallurgy and the conductive via.

### BACKGROUND

Since the invention of the integrated circuit (IC), the semiconductor industry has experienced rapid growth due to continuous improvements in the integration density of various electronic components (i.e., transistors, diodes, resistors, capacitors, etc.). For the most part, this improvement in integration density has come from repeated reductions in minimum feature size, which allows more components to be integrated into a given area. In an attempt to further increase circuit density, three-dimensional (3D) ICs have been investigated.

In some packaging technologies, integrated circuit dies are singulated from wafers before they are packaged. An advantageous feature of this packaging technology is the possibility of forming fan-out packages, which allow the I/O pads on a die to be redistributed to a greater area. The number of I/O pads on the surfaces of the dies may thus be increased.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of an integrated circuit die, in accordance with some embodiments.

FIGS. 2-5F and 6-11 illustrate various views of intermediate steps during a process for forming a package component, in accordance with some embodiments.

FIG. 5G is a perspective view image illustrating a void free interface between a conductive line and a conductive via, in accordance with some embodiments.

FIGS. 12 and 13 illustrate a various view of a process for securing a package component between a thermal module and a mechanical brace, in accordance with some embodiments.

FIG. 14 illustrates a resulting system-on-wafer assembly using the package component, in accordance with various embodiments

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, conductive vias and overlying conductive lines of a fan-out redistribution structure are formed with a high quality interface for use in electrical device packaging. Voids at the upper surfaces of the conductive vias may be eliminated (or at least substantially reduced), even when the interface between the upper surfaces of the conductive vias are recessed relative to overlying conductive lines. In some embodiments, the methods and structures described herein can reduce recessing of the upper surfaces of the conductive vias and increase step coverage for seed layers of the overlying conductive lines, and therefore can substantially reduce and/or eliminate the likelihood of voids forming between the conductive lines and vias.

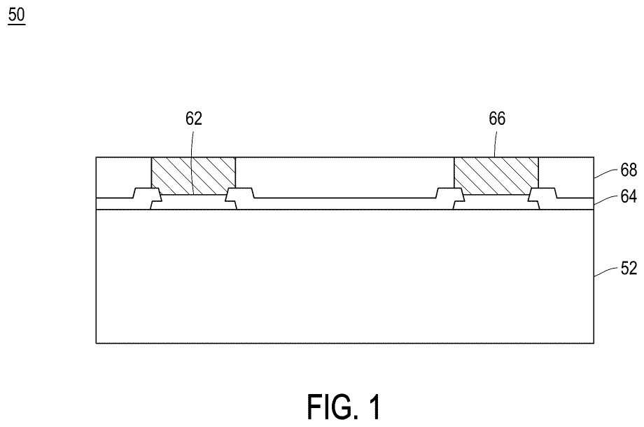

FIG. 1 illustrates a cross-sectional view of an integrated circuit die 50, in accordance with some embodiments. The integrated circuit die 50 will be packaged in subsequent processing to form an integrated circuit package. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), an application-specific die (e.g., an application-specific integrated circuit (ASIC), a field-programmable gate array (FPGA), etc.), the like, or combinations thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1), sometimes called a front side, and an inactive surface (e.g., the surface facing downwards in FIG. 1), sometimes called a back side. Devices may be formed at the front surface of the semiconductor substrate 52. The devices may be active devices (e.g., transistors, diodes, etc.), capacitors, resistors, etc. An interconnect structure is over the semiconductor substrate 52, and interconnects the devices to form an integrated circuit. The interconnect structure may be formed by, for example, metallization patterns in dielectric layers on the semiconductor substrate 52. The metallization patterns include metal lines and vias formed in one or more low-k dielectric layers. The metallization patterns of the interconnect structure are electrically coupled to the devices of the semiconductor substrate 52.

The integrated circuit die 50 further includes pads 62, such as aluminum pads, to which external connections are made. The pads 62 are on the active side of the integrated circuit die 50, such as in and/or on the interconnect structure. One or more passivation films 64 are on the integrated circuit die 50, such as on portions of the interconnect structure and pads 62. Openings extend through the passivation films 64 to the pads 62. Die connectors 66, such as conductive pillars (for example, formed of a metal such as copper), extend through the openings in the passivation films 64 and are physically and electrically coupled to respective ones of the pads 62. The die connectors 66 may be formed by, for example, plating, or the like. The die connectors 66 electrically couple the respective integrated circuits of the integrated circuit die 50.

Optionally, solder regions (e.g., solder balls or solder bumps) may be disposed on the pads 62. The solder balls may be used to perform chip probe (CP) testing on the integrated circuit die 50. CP testing may be performed on the integrated circuit die 50 to ascertain whether the integrated circuit die 50 is a known good die (KGD). Thus, only integrated circuit dies 50, which are KGDs, undergo subsequent processing are packaged, and dies, which fail the CP testing, are not packaged. After testing, the solder regions may be removed in subsequent processing steps.

A dielectric layer 68 may (or may not) be on the active side of the integrated circuit die 50, such as on the passivation films 64 and the die connectors 66. The dielectric layer 68 laterally encapsulates the die connectors 66, and the dielectric layer 68 is laterally coterminous with the integrated circuit die 50. Initially, the dielectric layer 68 may bury the die connectors 66, such that the topmost surface of the dielectric layer 68 is above the topmost surfaces of the die connectors 66. In some embodiments where solder regions are disposed on the die connectors 66, the dielectric layer 68 may also bury the solder regions. Alternatively, the solder regions may be removed prior to forming the dielectric layer 68.

The dielectric layer 68 may be a polymer such as polybenzoxazole (PBO), polyimide, benzocyclobutene (BCB), or the like; a nitride such as silicon nitride or the like; an oxide such as silicon oxide, phosphosilicate glass (PSG), borosilicate glass (BSG), boron-doped phosphosilicate glass (BPSG), or the like; the like, or a combination thereof. The dielectric layer 68 may be formed, for example, by spin coating, lamination, chemical vapor deposition (CVD), or the like. In some embodiments, the die connectors 66 are exposed through the dielectric layer 68 during formation of the integrated circuit die 50. In some embodiments, the die connectors 66 remain buried and are exposed during a subsequent process for packaging the integrated circuit die 50. Exposing the die connectors 66 may remove any solder regions that may be present on the die connectors 66.

In some embodiments, the integrated circuit die 50 is a stacked device that includes multiple semiconductor substrates 52. For example, the integrated circuit die 50 may be a memory device such as a hybrid memory cube (HMC) device, a high bandwidth memory (HBM) device, or the like that includes multiple memory dies. In such embodiments, the integrated circuit die 50 includes multiple semiconductor substrates 52 interconnected by through-substrate vias (TSVs). Each of the semiconductor substrates 52 may (or may not) have an interconnect structure.

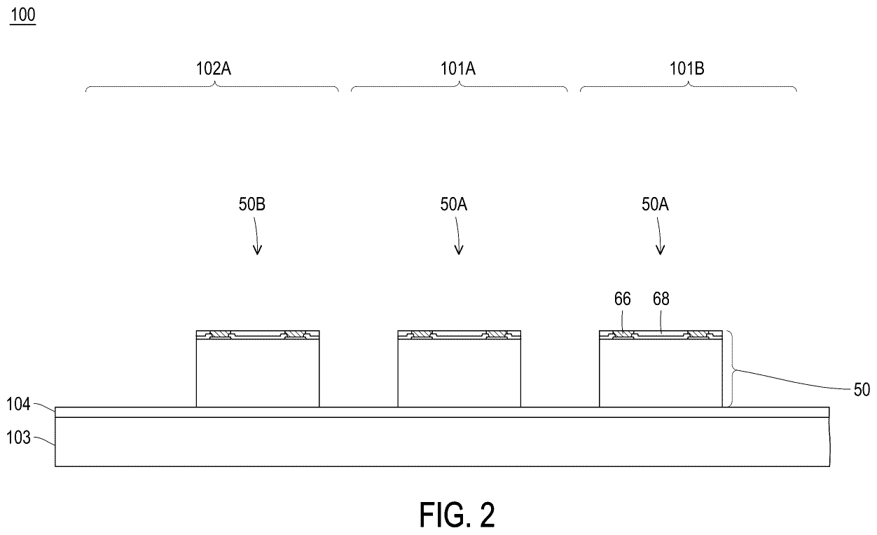

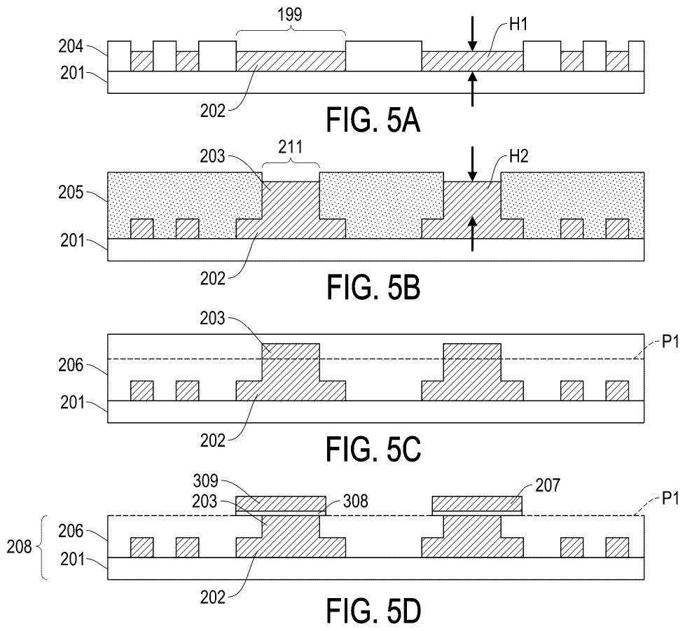

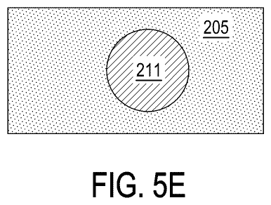

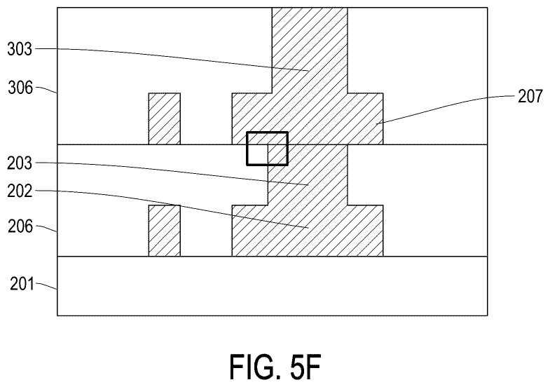

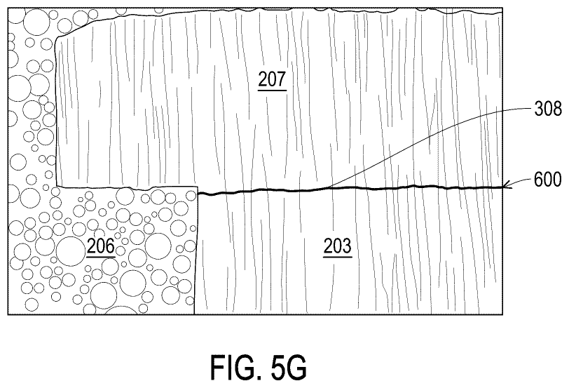

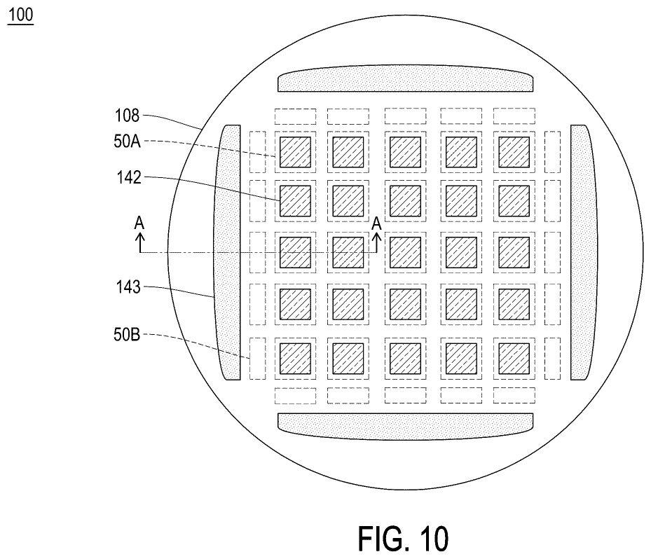

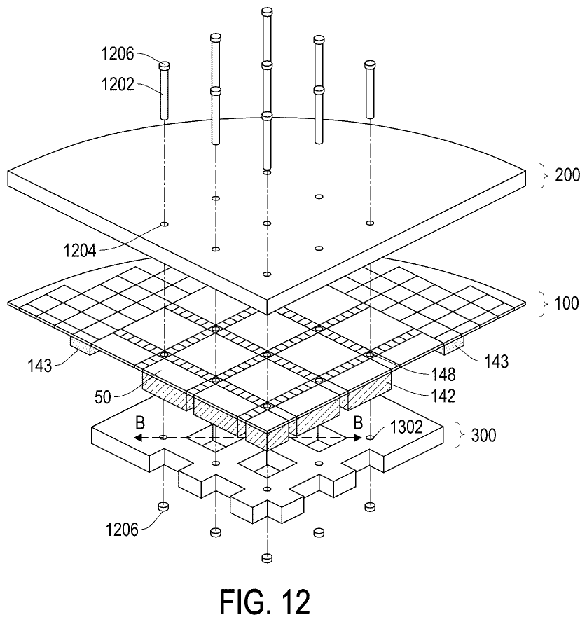

FIGS. 2 through 11 illustrate various views of intermediate steps during a process for forming a package component 100, in accordance with some embodiments. FIGS. 2, 3, 4, 5A, 5B, 5C, 5D, 5F, 6, 7, 8, 9, 11, 13, and 14 are cross-sectional views. FIGS. 5E and 10 are top-down views. FIG. 12 is a section view. FIG. 5G is a micrograph image. The package component 100 is a reconstructed wafer having multiple package regions, with one or more of the integrated circuit dies 50 being packaged in each of the package regions. The package regions include computing sites 101 and connecting sites 102. Each of the computing sites 101 may have e.g., logic functions, memory functions, or the like, and the package component 100 may be a single computing device comprising the computing sites 101 and connecting sites 102, such as a system-on-wafer (SoW) device. For example, the package component 100 may be an artificial intelligence (AI) accelerator, and each computing site 101 may be a neural network node for the AI accelerator. Each of the connecting sites 102 may have, e.g., external connectors, and the computing sites 101 of the package component 100 may connect to external systems through the connecting sites 102. Example systems for the package component 100 include AI servers, high-performance computing (HPC) systems, high power computing devices, cloud computing systems, edge computing systems, and the like. Two computing sites 101, e.g., computing sites 101A and 101B, and one connecting site 102, e.g., connecting site 102A, are illustrated, but it should be appreciated that the package component 100 may include many computing sites 101 and connecting sites 102, and the sites may be laid out in a variety of manner. Example layouts for the package component 100 are illustrated and discussed with respect to FIG. 10. FIGS. 2, 3, 4, 6, 7, 8, 9, and 11 only show a portion of the package component 100, such as that indicated by cross-section A-A in FIG. 10.

The devices of the package component 100 are interconnected by a redistribution structure. The conductive features of the redistribution structure may have void free interfaces. FIG. 5G is a perspective view image illustrating a void free interface between a conductive line and a conductive via. Void free interfaces may be formed by minimizing the depth that the upper surface of conductive vias is recessed. Recessing the upper surface of the conductive vias may be minimized by forming the conductive vias, backfilling a dielectric layer to cover the conductive vias, planarizing the backfilled dielectric layer and upper surface of the conductive vias, and then forming conductive lines atop the planarized conductive vias.

In FIG. 2, a carrier substrate 103 is provided, and an adhesive layer 104 is formed on the carrier substrate 103. The carrier substrate 103 may be a glass carrier substrate, a ceramic carrier substrate, or the like. The carrier substrate 103 may be a wafer, such that multiple packages can be formed on the carrier substrate 103 simultaneously. The adhesive layer 104 may be removed along with the carrier substrate 103 from the overlying structures that will be formed in subsequent steps. In some embodiments, the adhesive layer 104 is any suitable adhesive, epoxy, die attach film (DAF), or the like, and is applied over the surface of the carrier substrate 103.

Integrated circuit dies 50 are then attached to the adhesive layer 104. A desired type and quantity of integrated circuit dies 50 are attached in each of the computing sites 101A and 101B and the connecting site 102A. In some embodiments, a first type of integrated circuit die, such as a SoC die 50A, is attached in each computing site 101A and 101B, and a second type of integrated circuit die, such as an I/O interface die 50B, is attached in the connecting site 102A. Although a single integrated circuit die 50 is illustrated in each site, it should be appreciated that multiple integrated circuit dies may be attached adjacent one another some or all of the sites. When multiple integrated circuit dies are attached in each computing site 101A and 101B, they may be of the same technology node, or different technology nodes. For example, the integrated circuit dies 50 may include dies formed at a 10 nm technology node, dies formed at a 7 nm technology node, the like, or combinations thereof.

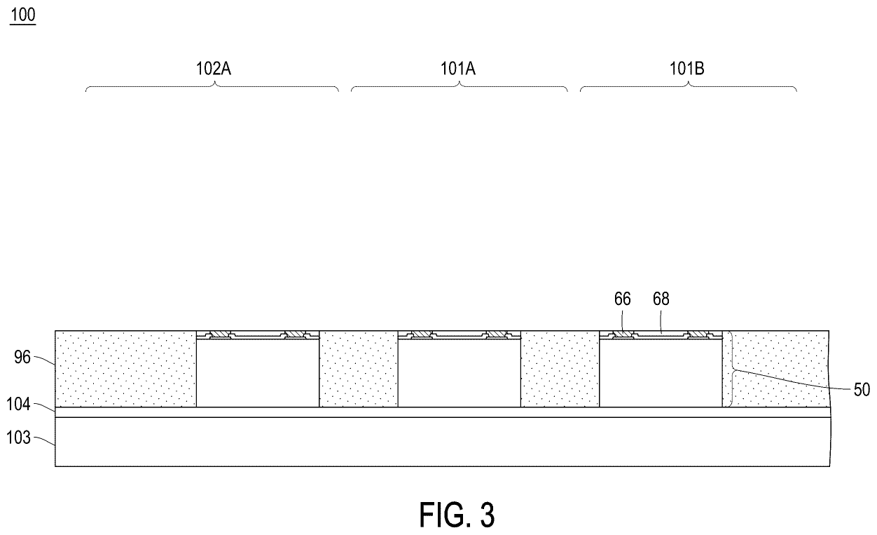

In FIG. 3, an encapsulant 96 is formed on and around the various components. After formation, the encapsulant 96 encapsulates the integrated circuit dies 50. The encapsulant 96 may be a molding compound, epoxy, or the like, and may be applied by compression molding, transfer molding, or the like. The encapsulant 96 may be applied in liquid or semi-liquid form and then subsequently cured. In some embodiments, the encapsulant 96 is formed over the carrier substrate 103 such that the integrated circuit dies 50 are buried or covered, and a planarization process is then performed on the encapsulant 96 to expose the die connectors 66 of the integrated circuit dies 50. Topmost surfaces of the encapsulant 96, die connectors 66, and dielectric layers 68 are coplanar after the planarization process. The planarization process may be, for example, a chemical-mechanical polish (CMP).

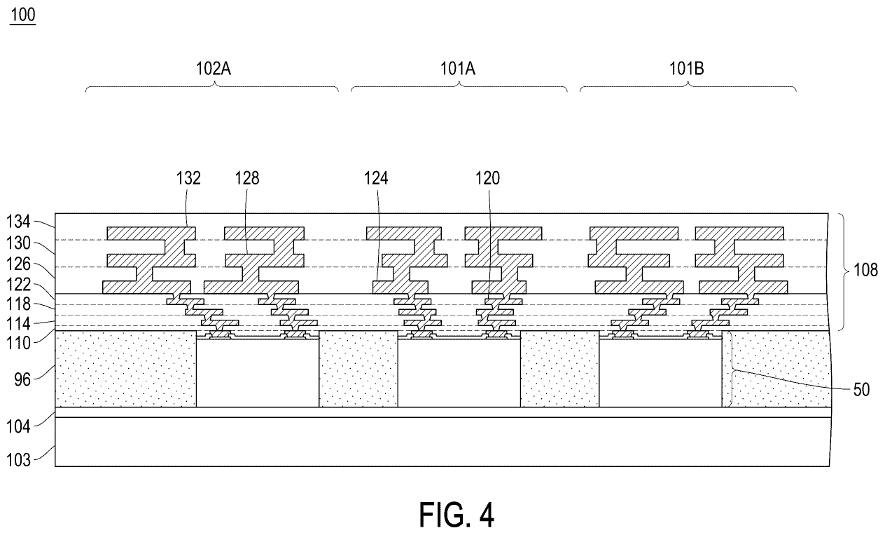

In FIG. 4, a redistribution structure 108 is formed over the encapsulant 966 and integrated circuit dies 50. The redistribution structure 108 includes metallization patterns and dielectric layers. The metallization patterns may also be referred to as redistribution layers or redistribution lines. The redistribution structure 108 is shown as an example having six layers of metallization patterns. More or fewer dielectric layers and metallization patterns may be formed in the redistribution structure 108. If fewer dielectric layers and metallization patterns are to be formed, steps and process discussed below may be omitted. If more dielectric layers and metallization patterns are to be formed, steps and processes discussed below may be repeated. In this example, the redistribution structure 108 includes dielectric layers 110, 114, 118, 122, 126, 130, 134 and also includes metallization patterns 112, 116, 120, 124, 128, 132. The metallization patterns 112, 116, 120, 124, 128, 132 may include horizontally orientated conductive lines and vertically orientated conductive vias.

FIGS. 5A-5F illustrate some embodiments of forming layers of the redistribution structure 108 depicted in FIG. 4. Specifically, a process for forming metallization patterns and dielectric layers is shown. Each metallization pattern includes conductive vias and overlying conductive lines on the conductive vias. The metallization patterns of the redistribution structure 108 are formed using a process that produces a high quality interface between the upper surfaces of the conductive vias and the overlying conductive lines. The interface may be free of voids.

In FIG. 5A, a first dielectric layer 201 and first conductive lines 202 of the redistribution structure are formed. In some embodiments, the first dielectric layer 201 may be formed of a polymeric material. For example, the polymeric material for the first dielectric layer 201 may include compositions such as polyimide (PI), benzocyclobutene (BCB), and polybenzoxazole (PBO). The first dielectric layer 201 may provide the layer of the redistribution structure 108 that may be formed on the die connectors 66, dielectric layer 68 and encapsulant 96, as described above with reference to FIG. 4.

As an example to form the first conductive lines 202, a seed layer is formed over the first dielectric layer 201. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A first mask structure 204 is then formed and patterned on the seed layer. The first mask structure 204 may be formed by spin coating or the like and may be exposed to light for patterning. The pattern of the first mask structure 204 corresponds to the first conductive lines 202. The patterning forms first openings 199 through the first mask structure 204 to expose the seed layer. A conductive material is then formed in the first openings 199 of the first mask structure 204 and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the first conductive lines 202. The first mask structure 204 and portions of the seed layer on which the conductive material is not formed are removed. The first mask structure 204 may be removed by an acceptable ashing or stripping process, such as using an oxygen plasma or the like. Once the first mask structure 204 is removed, exposed portions of the seed layer are removed, such as by using an acceptable etching process, such as by wet or dry etching. The remaining portions of the seed layer and conductive material form the first conductive lines 202.

In some embodiments, the first openings 199 in the first mask structure 204 have a geometry for providing the first conductive lines 202. In some embodiments, the first conductive lines 202 are configured to provide horizontal electrical signal distribution across the package component 100.

The thickness of the electrically conductive fill material for the multilayered first conductive lines 202 may be plated to a thickness suitable for a low electrical resistance structure for transmitting electrical signals. The electrically conductive fill material may not be plated to fill the entire height of the first openings 199 in the first masking structure 204. In the embodiment depicted in FIG. 5A, the upper surface of the electrically conductive fill material is recessed relative to the upper surface of the first masking structure 204. In some embodiments, the first conductive lines 202 may have a height H1 ranging from 10 microns to 20 microns. In one example, the first conductive lines 202 has a height H1 of 15 microns.

In FIG. 5B, conductive vias 203 are formed atop the first conductive lines 202. The first conductive vias 203 provide vertical electrical signal distribution through the package component 100. For example, the first conductive via 203 may transmit an electrical signal from an underlying first conductive line 202 to an overlying under-bump metallurgy (UBM) and/or second conductive line.

As an example to form the conductive vias 203, a second masking structure 205 may be formed atop the first conductive lines 202, wherein second openings 211 in the second masking structure 205 are filled with a second conductive material to provide first the conductive vias 203. In some embodiments, the first masking structure 204 is removed prior to forming the second masking structure 205. The first masking structure 204 when formed of a photoresist material may be removed by wet chemical stripping and/or plasma ashing. Following removal of the first masking structure 204, the second masking structure 205 may be formed.

In some embodiments, the second masking structure 205 is formed of a photoresist material. The second masking structure 205 may be similar to the first masking structure 204. Therefore, the above description of the composition and method of forming the first masking structure 204 depicted in FIG. 5A may provide details for forming the second masking structure 205 that is depicted in FIG. 5B. The second masking structure is deposited to a thickness that covers the entirety of the first conductive lines 202, and has a thickness atop the first conductive lines 202 for at least a height of the first conductive vias 203.

In some embodiments, a photoresist material layer is deposited for the second masking structure 205, and is patterned using photolithography to provide second openings 211 having a geometry suitable for the first conductive vias 203. As illustrated in FIG. 5B, the width of the second openings 211 is less than the width of the first openings 199. FIG. 5E illustrates from a top down view the circular aperture for one embodiment of the geometry for the second openings 211. In some embodiments, the radius for the circular aperture that provides the second openings 211 may be about 0.05 microns.

Following the formation of the second masking structure 205, the second openings 211 may be filled with an electrically conductive material to provide the first conductive vias 203. In some embodiments, the electrically conductive material that is formed within the second openings 211 to provide the first conductive vias 203 may be a multi-layered structure. In some embodiments, the electrically conductive material for the first conductive vias 203 can include at least one adhesion layer and an electrically conductive fill. The adhesion layer and electrically conductive fill for the first conductive vias 203 is similar to the adhesion layer and the electrically conductive fill for the first conductive lines 202.

In FIG. 5C, the second masking structure 205 is removed, and a first dielectric layer 206 is formed onto the first dielectric layer 201, the first conductive lines 202, and the first conductive vias 203. In some embodiments, the dielectric layer 114 is formed of a molding compound. The molding compound may include a resin having fillers disposed therein. Examples of resins include epoxy, acrylic, or polyimide-based materials. Examples of fillers include silica or the like. The molding compound may be applied by compression molding, transfer molding, or the like, and may be applied in liquid or semi-liquid form and then subsequently cured. In some embodiments, the dielectric material of the first dielectric layer 206 may have a dielectric constant of less than 3.5.

The thickness of the first dielectric layer 206 is controlled to cover the upper surface of the first conductive vias 203. For example, the first dielectric layer 206 may be deposited to a thickness having a height greater than a planarization plane P1. The planarization plane P1 is the height at which a subsequent planarization step is terminated to planarize the upper surface of the first dielectric layer 206 to be coplanar with the upper surface of the first conductive vias 203.

In FIG. 5D, the first dielectric layer 206 is planarized to expose the upper surfaces of the first conductive vias 203. In some embodiments, the upper surface of the redistribution structure 208 may be planarized using a planarization process, such as chemical mechanical planarization (CMP). For example, the planarization process may continue until reaching the planarization plane P1 that is first depicted in FIG. 5C. At that depth of planarization plane P1, the upper surface of the first dielectric layer 206 is substantially coplanar with the upper surface of the first conductive vias 203. For example, the height difference between the upper surface of the first dielectric layer 206 and any recess in the upper surface of the first conductive vias 203 is no greater than 0.25 microns. For example, the height difference between the upper surface of the first dielectric layer 206 and the upper surface of the first conductive vias 203 may range from 0.10 microns to 0.20 microns. In one example, the height difference between the upper surface of the first dielectric layer 206 and the upper surface of the first conductive via 203 may be equal to 0.17 microns.

In FIG. 5D, second conductive lines 207 are formed on the planarized upper surfaces of the first dielectric layer 206 and the first conductive vias 203. The second conductive lines 207 may be formed from electrically conductive material. In some embodiments, the second conductive lines 207 may be formed of a seed layer 308 and a conductive material 309.

As an example to form the second conductive lines 207, a seed layer 308 is formed over the first dielectric layer 206 and the first conductive vias 203. In some embodiments, the seed layer 308 is a metal layer, which may be a single layer or a composite layer comprising a plurality of sub-layers formed of different materials. In some embodiments, the seed layer 308 comprises a titanium layer and a copper layer over the titanium layer. The seed layer 308 may be formed using, for example, physical vapor deposition (PVD) or the like. A photoresist is then formed and patterned on the seed layer 308. The photoresist may be formed by spin coating or the like and may be exposed to light for patterning. The pattern of the photoresist corresponds to the second conductive lines 207. The patterning forms openings through the photoresist to expose the seed layer 308. The conductive material 309 is then formed in the openings of the photoresist and on the exposed portions of the seed layer 308. The conductive material 309 may be formed by plating, such as electroplating or electroless plating, or the like. The conductive material 309 may comprise a metal, like copper, titanium, tungsten, aluminum, or the like. The combination of the conductive material 309 and underlying portions of the seed layer 308 form the second conductive lines 207. The photoresist and portions of the seed layer 308 on which the conductive material 309 is not formed are removed. The photoresist may be removed by an acceptable ashing or stripping process, such as using an oxygen plasma or the like. Once the photoresist is removed, exposed portions of the seed layer 308 are removed, such as by using an acceptable etching process, such as by wet or dry etching. The remaining portions of the seed layer 308 and conductive material 309 form the second conductive lines 207.

The redistribution structure 208 depicted in FIG. 4 includes six layers of conductive lines and dielectric layers. It should be appreciated that any number of layers may be formed by repeating the steps described herein.

In FIG. 5F, second conductive vias 303 are formed, and a second dielectric layer 306 is formed. The second conductive vias 303 may be similar to the first conductive vias 203. Therefore, the above description of forming the first conductive vias 203 that is provided with reference to FIG. 5A is suitable for describing forming the second conductive vias 303 depicted in FIG. 5F. The second dielectric layer 306 may be similar to the first dielectric layer 206 that is described above with reference to FIG. 5C. Therefore, the above description of forming the first dielectric layer 206 that is provided with reference to FIG. 5C is suitable for describing forming the second dielectric layer 306 depicted in FIG. 5F.

FIG. 5G is a perspective view image of an interface 600 between a conductive via, e.g., a first conductive via 203 formed of a copper, and a titanium adhesion layer, e.g., the seed layer 308 of a second conductive line 207. The upper surface of the first conductive via 203 is recessed from the upper surface of the first dielectric layer 206. The recess is small; in some embodiments, the depth different between the upper surface of the first dielectric layer 206 and the upper surface of the first conductive via 203 provided by the methods described with reference to FIGS. 5A-5F is no greater than 0.25 microns. As described above, the difference between the upper surface of the first dielectric layer 206 and any recess in the upper surface of the first conductive via 203 is minimized by forming the first conductive via 203, backfilling the first dielectric layer 206 to cover the first conductive via 203, planarizing the backfilled first dielectric layer 206 and upper surface of the first conductive via 203, and then forming the second conductive line 207 atop the planarized first conductive via 203 and first dielectric layer 206.

In FIG. 5G, the difference between the upper surface of the first dielectric layer 206 and the upper surface of the first conductive via 203 may be about 0.17 microns. In some embodiments by minimizing the difference between the upper surface of the first dielectric layer 206 and the upper surface of the first conductive via 203, the incidence of voids at the interface 600 is minimized or substantially eliminated. For example, the interface 600 between the adhesion layer of the overlying electrically conductive feature (e.g., second conductive line 207) is in direct contact with the planarized upper surface of the first dielectric layer 206, the planarized upper surface of the first conductive via 203 and any sidewall of the first fill material 206 that results from the recess between the planarized upper surfaces of the first fill material 206 and the first conductive via 203. The seed layer 308 extends along the upper surface of the first dielectric layer 206, down the sidewall of the first dielectric layer 206 forming the recess, and along the upper surface of the first conductive via 203. There may be no voids between the seed layer 308 and the upper surface of the first dielectric layer 206, the sidewall of the first dielectric layer 206 forming the recess, or the upper surface of the first conductive via 203.

In FIG. 5G, no voids are present between the lower surface of the second conductive line 207 and the first conductive via 203 and any sidewall of the first fill material 206. Thus, there are no voids between the second conductive line 207 and the first conductive via 203. Further, there are no voids present between the electrically conductive material and the adhesion layer of the first conductive via 203.

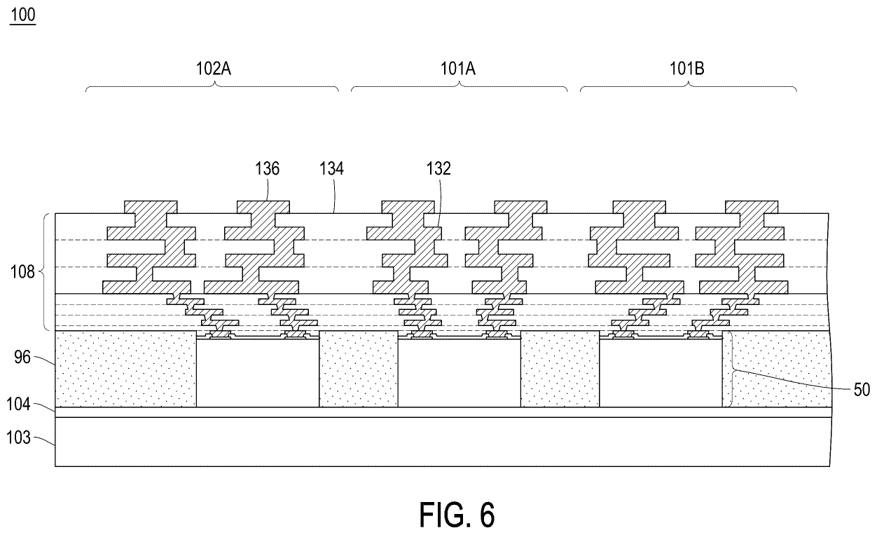

In FIG. 6, UBMs 136 are formed for external connection to the redistribution structure 108. The UBMs 136 have bump portions on and extending along the upper surfaces of the upper dielectric layer 134 and the upper metallization pattern 132. As a result, the UBMs 136 are electrically coupled to the integrated circuit dies 50. The UBMs 136 may be formed in a similar manner as the conductive lines of the redistribution structure 108 (previously described), except the UBMs 136 may have other types and quantities of layers. In some embodiments, the UBMs 136 have a different size than the metallization patterns 112, 116, 120, 124, 128, and 132.

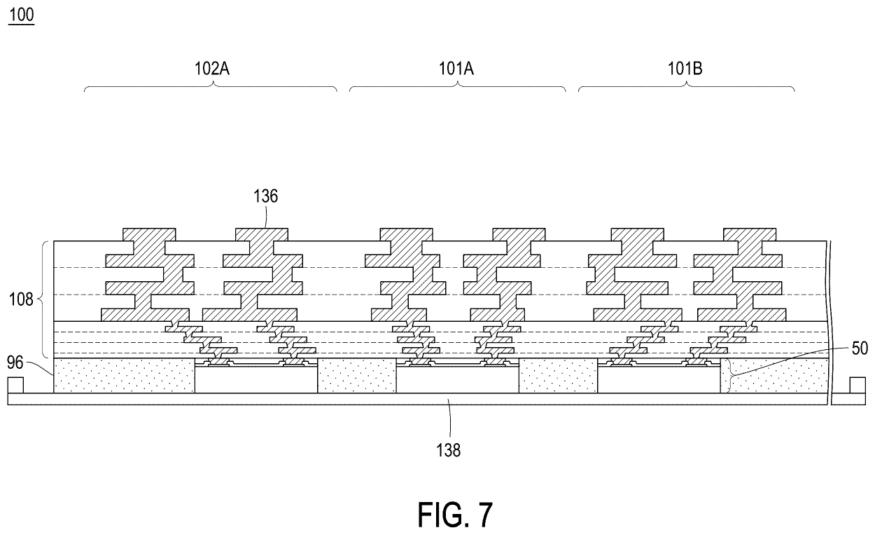

In FIG. 7, a carrier substrate debonding is performed to detach (or “debond”) the carrier substrate 103 from the encapsulant 96 and integrated circuit dies 50. In some embodiments, the debonding includes removing the carrier substrate 103 and adhesive layer 104 by, e.g., a grinding or planarization process, such as a CMP. After removal, back side surfaces of the integrated circuit dies 50 are exposed, and the back side surfaces of the encapsulant 96 and integrated circuit dies 50 are level. The structure is then placed on a tape 138. As discussed further below, the package component 100 experiences a large amount of wafer warpage when debonded from the carrier substrate 103.

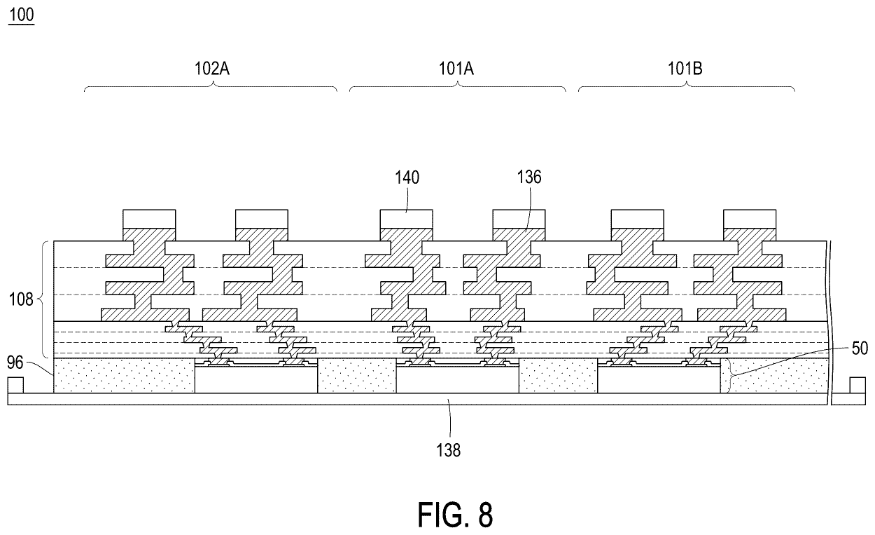

In FIG. 8, conductive connectors 140 are formed on the UBMs 136. The conductive connectors 140 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 140 may include a conductive material such as solder, copper, aluminum, gold, nickel, silver, palladium, tin, the like, or a combination thereof. In some embodiments, the conductive connectors 140 are formed by initially forming a layer of solder or solder paste through evaporation, electroplating, printing, solder transfer, ball placement, or the like. Once a layer of solder has been formed on the structure, a reflow may be performed in order to shape the material into the desired bump shapes.

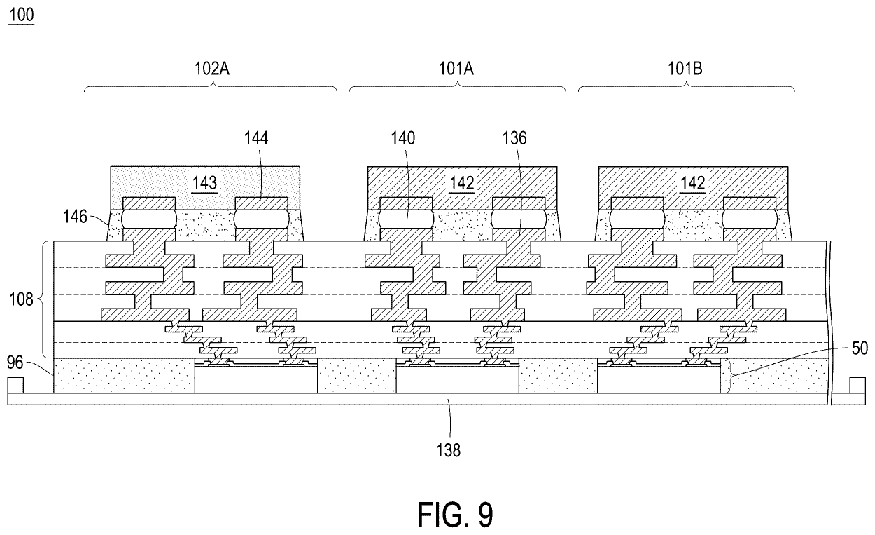

In FIG. 9, sockets 142 and connectors 143 are attached to the redistribution structure 108. The sockets 142 and connectors 143 are interfaces for external connection to the package component 100. The sockets 142 and connectors 143 include pads 144, such as aluminum pads, to which external connections are made. The sockets 142 and connectors 143 are mounted to the UBMs 136 using the conductive connectors 140. In the embodiment shown, the sockets 142 are attached at the computing sites 101A and 101B, and the connectors 143 are attached at the connecting site 102A. An underfill 146 is formed to fill the gaps between the sockets 142 and connectors 143 and the redistribution structure 108. The underfill 146 may be formed by a capillary flow process after the sockets 142 and connectors 143 are attached, or may be formed by a suitable deposition method before the sockets 142 and connectors 143 are attached.

The sockets 142 are electrical and physical interfaces for modules (discussed further below) that may be installed at the computing sites 101A and 101B subsequent to manufacture of the package component 100. For example, a user of the package component 100 may install modules in the sockets 142 to form completed functional systems at the computing sites 101A and 101B. The type of modules selected for installation depends on the type of functional systems desired at the computing sites 101A and 101B. Examples of modules that may be installed in the sockets 142 include memory modules, voltage regulator modules, power supply modules, integrated passive device (IPD) modules, and the like. The sockets 142 may include different components, such as a chassis and contact pins, which may comprise different materials.

The connectors 143 are electrical and physical interfaces for the package component 100 to external systems. For example, when the package component 100 is installed as part of a larger external system, such as a data center, the connectors 143 may be used to couple the package component 100 to the external system. Examples of connectors 143 include receptors for ribbon cables, flexible printed circuits, or the like.

The sockets 142 and connectors 143 may be attached to the redistribution structure 108 in a variety of layouts. The layout shown in FIG. 9 is one example. FIG. 10 is a top-down view of the package component 100 showing another example layout for the sockets 142 and connectors 143. Each socket 142 directly overlies and is electrically coupled to the SoC dies 50A of a corresponding computing site 101A or 101B. The connectors 143 are disposed around the perimeter of the package component 100, thus increasing the area available for the sockets 142. The connecting site 102A may include one or more connectors 143. In the illustrated embodiment, the connectors 143 are laterally offset from the I/O interface dies 50B. In another embodiment, the connectors 143 directly overly the I/O interface dies 50B.

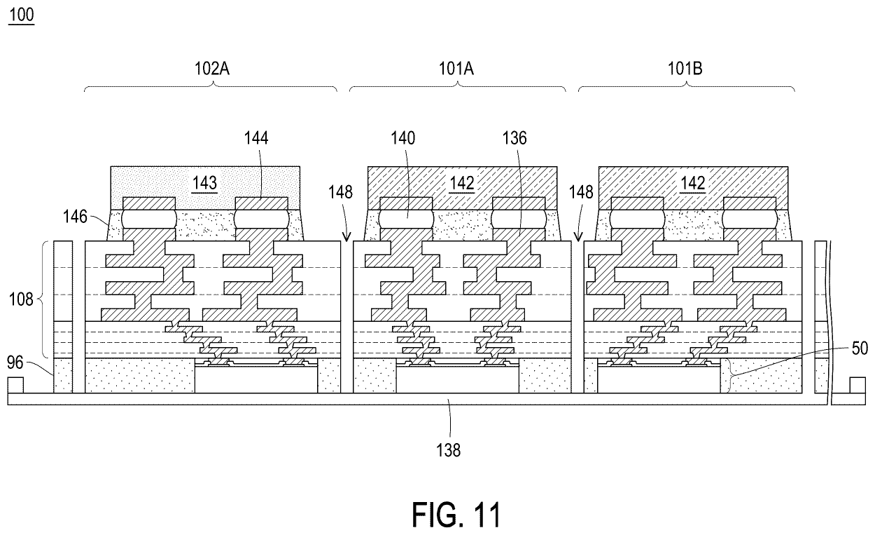

In FIG. 11, bolt holes 148 are formed through the package component 100. The bolt holes 148 may be formed by a drilling process such as laser drilling, mechanical drilling, or the like. The bolt holes 148 may be formed by drilling an outline for the bolt holes 148 with the drilling process, and then removing the material separated by the outline.

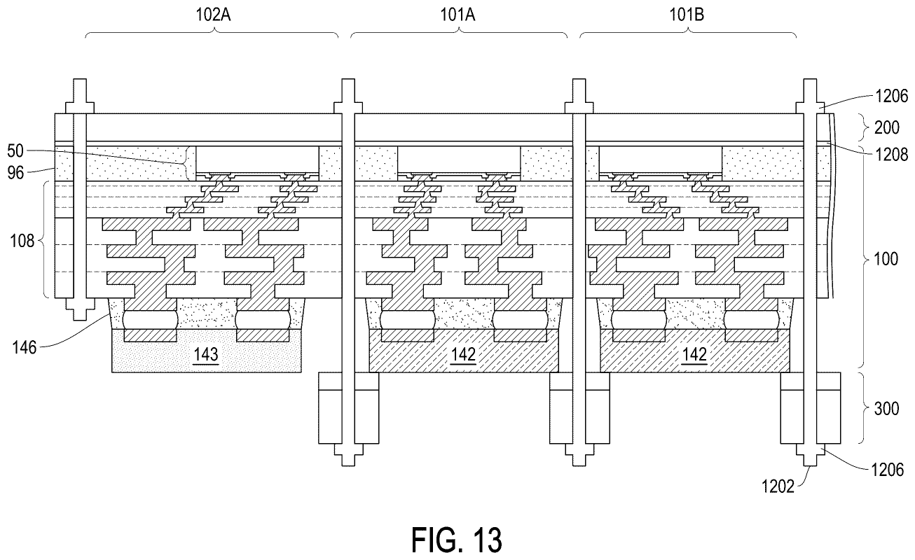

FIGS. 12 and 13 illustrate various view of a process for securing the package component 100 between a thermal module 200 and a mechanical brace 300, in accordance with some embodiments. The thermal module 200 may be a heat sink, a heat spreader, a cold plate, or the like. The mechanical brace 300 is a rigid support that physically engages portions of the sockets 142, securing the sockets 142 when modules are installed or removed. Warpage of the package component 100, such as that induced by carrier substrate debonding, may be reduced by clamping the package component 100 between the thermal module 200 and mechanical brace 300. FIG. 12 is a three-dimensional view illustrating one quarter of the package component 100, thermal module 200, and mechanical brace 300 during assembly, in accordance with some embodiments. Some details are omitted in FIG. 12 for clarity of illustration. FIG. 13 is a cross-sectional view illustrating portions of the package component 100, thermal module 200, and mechanical brace 300 after assembly, and is described in conjunction with FIG. 12. FIG. 13 is illustrated along reference cross-section B-B in FIG. 12.

The package component 100 is removed from the tape 138 and is fastened between the thermal module 200 and mechanical brace 300 with bolts 1202. The bolts 1202 are threaded through the bolt holes 148 of the package component 100, through corresponding bolt holes 1204 in the thermal module 200, and through corresponding bolt holes 1302 in the mechanical brace 300. Fasteners 1206 are threaded onto the bolts 1202 and tightened to clamp the package component 100 between the thermal module 200 and mechanical brace 300. The fasteners 1206 may be, e.g., nuts that thread to the bolts 1202. The fasteners 1206 attach to the bolts 1202 at both sides of the resulting system-on-wafer assembly (e.g., at the side having the thermal module 200 (sometimes referred to as the back side) and at the side having the mechanical brace 300 (sometimes referred to as the front side)).

Before fastening together the various components, a thermal interface material (TIM) 1208 (see FIG. 13) is dispensed on the back side of the package component 100, physically and thermally coupling the thermal module 200 to the integrated circuit dies 50. During fastening, the fasteners 1206 are tightened, thereby increasing the mechanical force applied to the package component 100 by the thermal module 200 and the mechanical brace 300. The fasteners 1206 are tightened until the thermal module 200 exerts a desired amount of pressure on the TIM 1208.

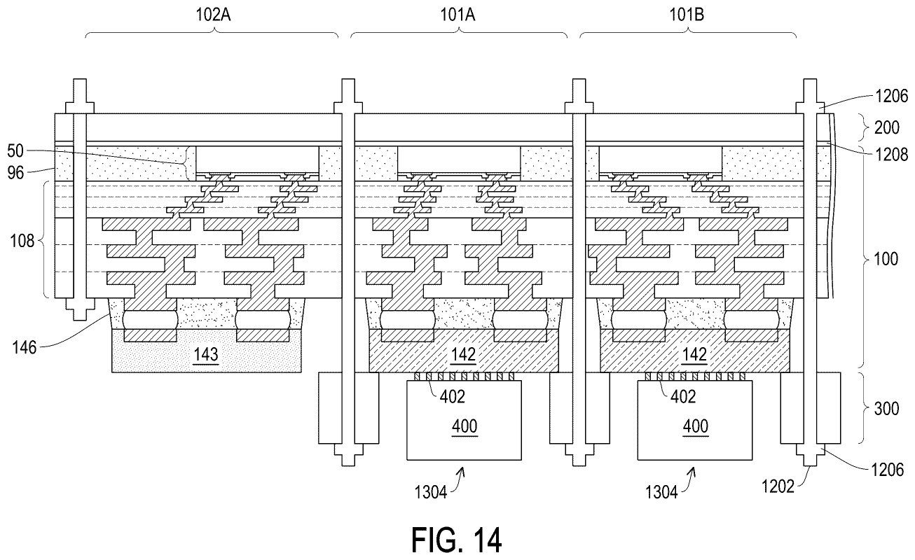

FIG. 14 illustrates a cross-sectional view of the resulting system-on-wafer assembly after modules 400 are installed in the sockets 142. FIG. 14 is illustrated along reference cross-section B-B in FIG. 12. As noted above, the modules 400 may be memory modules, voltage regulator modules, power supply modules, integrated passive device (IPD) modules, and the like. The modules 400 comprise conductive connectors 402, which are inserted in corresponding receptors to physically and electrically couple the contact pins of the sockets 142. The modules 400 are thus secured in the sockets 142, forming completed functional systems at the computing sites 101A and 101B. After installation, the modules 400 are disposed in the openings 1304 of the mechanical brace 300.

In some embodiments, the methods and structures can provide a redistribution structure process flow that provides for excellent alignment conditions, and provides a high quality of interface between the upper surfaces of the conductive vias and the overlying conductive lines. In some embodiments, the recesses between the upper surfaces of the conductive via and the upper surface of a surrounding dielectric layer is limited to a difference in height between the upper surface of the dielectric layer and the via surfaces of 0.5 microns or less. By reducing the recesses of the upper surfaces of the conductive vias, adhesion layer coverage, e.g., titanium coverage, for the overlying conductive lines may be as great as 100%. In some embodiments, the incidence of voids between at the interfaces of the conductive vias and the conductive lines is substantially eliminated.

In accordance with an embodiment, a method comprising: forming a first electrically conductive material in a first opening of a first masking structure to provide a first conductive line; forming a second electrically conductive material in a second opening of a second masking structure to provide a conductive via on the first conductive line; removing the second masking structure; forming a dielectric layer covering the first conductive line and the conductive via; planarizing the dielectric layer to expose an upper surface of the conductive via, the upper surface of the conductive via being recessed from an upper surface of the dielectric layer after the planarizing; and forming conductive feature comprising a seed layer atop the upper surface of the conductive via, wherein the seed layer covers the upper surface of the conductive via and the upper surface of the dielectric layer. In one embodiment, the method further comprises removing the first masking structure before forming the second masking structure. In some embodiments, the seed layer covers a sidewall of the dielectric layer between the upper surface of the conductive via and the upper surface of the dielectric layer. In some embodiments, a difference in height between the upper surface of the conductive via and the upper surface of the dielectric layer after the planarizing of the dielectric layer is less than 0.15 microns. In one embodiment, the conductive feature comprises a second conductive line. In one embodiment, the conductive feature comprises an under-bump metallurgy. In one embodiment, the seed layer comprises titanium and copper on the titanium. In one embodiment, the seed layer completely covers the conductive via from one edge of the upper surface of the conductive via to an opposing second edge of the upper surface of the conductive via without any voids between the seed layer and the upper surface of the conductive via.

In accordance with another embodiment, a method comprising forming a redistribution structure comprising forming a first conductive via in a first opening of a first masking structure, removing the first masking structure, forming a first dielectric layer covering the first conductive via, planarizing the first dielectric layer to expose an upper surface of the first conductive via, and forming a under-bump metallurgy comprising a first seed layer atop the upper surface of the first conductive via, wherein the first seed layer of the under-bump metallurgy completely covers a first interface between the under-bump metallurgy and the first conductive via. The method may also include bonding a module socket to the under-bump metallurgy of the redistribution structure. In one embodiment, a difference in height between the upper surface of the first conductive via and an upper surface of the first dielectric layer after the planarizing of the first dielectric layer is less than 0.15 microns. In one embodiment, the first seed layer comprises titanium and copper on the titanium. In one embodiment, the method further comprises forming a conductive line on a second conductive via, wherein the first conductive via is formed on the conductive line. In on embodiment, forming the conductive line comprises forming an electrically conductive material in a second opening of a second masking structure to provide the conductive line, wherein the second opening expose a planarized upper surface of the second conductive via, and removing the second masking structure.

In accordance with yet another embodiment, a device comprising a redistribution structure comprising a conductive via extending through a dielectric layer to a first conductive line, wherein an upper surface of the conductive via is recessed from an upper surface of the dielectric layer, and wherein a difference in height between the upper surface of the conductive via and the upper surface of the dielectric layer is no greater than 0.15 microns, and an under-bump metallurgy comprising a seed layer atop the upper surface of the conductive via and the upper surface of the dielectric layer, wherein the seed layer completely covers an interface between the under-bump metallurgy and upper surface of the conductive via, the interface being free of voids; and a module socket connected to the under-bump metallurgy. In some embodiments, the method further comprises a thermal module; and a mechanical brace, the redistribution structure disposed between the thermal module and the mechanical brace. In some embodiments, the device further includes bolts extending through the mechanical brace, the thermal module, and the redistribution structure. In some embodiments, the seed layer includes titanium and copper. In some embodiments, the device further includes a voltage regulator module in the module socket. In some embodiments, the device further includes a seed layer that has a conformal thickness and comprises a sidewall portion on a portion of the dielectric layer that is between the upper surface of the conductive via and the upper surface of the dielectric layer. In some embodiments, the seed layer completely and continuously covers the conductive via from one edge of the upper surface of the conductive via to an opposing second edge of the upper surface of the conductive via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first electrically conductive material in a first opening of a first masking structure to provide a first conductive line;
forming a second electrically conductive material in a second opening of a second masking structure to provide a conductive via on the first conductive line;
removing the second masking structure;
forming a dielectric layer covering the first conductive line and the conductive via;
planarizing the dielectric layer to expose an upper surface of the conductive via, the upper surface of the conductive via being recessed from an upper surface of the dielectric layer after the planarizing; and
forming conductive feature comprising a seed layer atop the upper surface of the conductive via, wherein the seed layer covers the upper surface of the conductive via and the upper surface of the dielectric layer.

2. The method of claim 1, further comprising removing the first masking structure before forming the second masking structure.

3. The method of claim 1, wherein the seed layer covers a sidewall of the dielectric layer between the upper surface of the conductive via and the upper surface of the dielectric layer.

4. The method of claim 1, wherein a difference in height between the upper surface of the conductive via and the upper surface of the dielectric layer after the planarizing of the dielectric layer is less than 0.15 microns.

5. The method of claim 1, wherein the conductive feature comprises a second conductive line.

6. The method of claim 1, wherein the conductive feature comprises an under-bump metallurgy.

7. The method of claim 1, wherein the seed layer comprises titanium and copper on the titanium.

8. The method of claim 1, wherein the seed layer completely covers the conductive via from one edge of the upper surface of the conductive via to an opposing second edge of the upper surface of the conductive via without any voids between the seed layer and the upper surface of the conductive via.

9. A method comprising:
forming a redistribution structure comprising:
forming a first conductive via in a first opening of a first masking structure,
removing the first masking structure,
forming a first dielectric layer covering the first conductive via,
planarizing the first dielectric layer to expose an upper surface of the first conductive via, and
forming a under-bump metallurgy comprising a first seed layer atop the upper surface of the first conductive via, wherein the first seed layer of the under-bump metallurgy completely covers a first interface between the under-bump metallurgy and the first conductive via; and
bonding a module socket to the under-bump metallurgy of the redistribution structure.

10. The method of claim 9, wherein a difference in height between the upper surface of the first conductive via and an upper surface of the first dielectric layer after the planarizing of the first dielectric layer is less than 0.15 microns.

11. The method of claim 9, wherein the first seed layer comprises titanium and copper on the titanium.

12. The method of claim 9, further comprising forming a conductive line on a second conductive via, wherein the first conductive via is formed on the conductive line.

13. The method of claim 12, wherein forming the conductive line comprises:
forming an electrically conductive material in a second opening of a second masking structure to provide the conductive line, wherein the second opening expose a planarized upper surface of the second conductive via; and
removing the second masking structure.

14. A device comprising:
a redistribution structure comprising:
a conductive via extending through a dielectric layer to a first conductive line, wherein an upper surface of the conductive via is recessed from an upper surface of the dielectric layer, and wherein a difference in height between the upper surface of the conductive via and the upper surface of the dielectric layer is no greater than 0.15 microns, and
an under-bump metallurgy comprising a seed layer atop the upper surface of the conductive via and the upper surface of the dielectric layer, wherein the seed layer completely covers an interface between the under-bump metallurgy and upper surface of the conductive via, the interface being free of voids; and
a module socket connected to the under-bump metallurgy.

15. The device of claim 14, further comprising:
a thermal module; and
a mechanical brace, the redistribution structure disposed between the thermal module and the mechanical brace.

16. The device of claim 15, further comprising:
bolts extending through the mechanical brace, the thermal module, and the redistribution structure.

17. The device of claim 14, wherein the seed layer comprises titanium and copper.

18. The device of claim 14, further comprising:
a voltage regulator module in the module socket.

19. The device of claim 14, wherein the seed layer has a conformal thickness and comprises a sidewall portion on a portion of the dielectric layer that is between the upper surface of the conductive via and the upper surface of the dielectric layer.

20. The device of claim 14, wherein the seed layer completely and continuously covers the conductive via from one edge of the upper surface of the conductive via to an opposing second edge of the upper surface of the conductive via.
